(19) United States
(12) Patent Application Publication
(10) Pub. No.: US 2008/0216307 A1
(43) Pub. Date: Sep. 11, 2008

(54) Personalized gauge kit and method of using

(76) Inventor: Lawrence Andrew Hoffman, Portland, OR (US)

Correspondence Address: MARK S. HUBERT P.C., 516 SE MORRISON- SUITE 1200, PORTLAND, OR, 97214, US

(21) Appl. No.: 11/716,113

(22) Filed: Mar. 10, 2007

(51) Int. Cl. H05K 13/04

(52) U.S. Cl. 29/729; 29/428; 340/815.78; 717/178

(57) ABSTRACT

The present invention is a kit for making an automotive gauge with personalized gauge faces that may be interchanged via an in situ removable front cover plate. The kit provides a gauge having a dust proof sealing front cover plate that may be unscrewed from the gauge body and a keyed removable indicating needle that allows a personally stylized gauge face to be installed. The face of the gauge is constructed through the use of a personal computer and printer in conjunction with a software program, provided with the kit, that allows the user to personally design the gauge face.

### BACKGROUND OF THE INVENTION

The present invention relates to an indicating gauge kit that allows the purchasing consumer to make a personalized gauge face on a computer or select a gauge face from a set of pre designed faces that can then be installed in the gauge prior to the installation of the gauge or in situ. More particularly, the present invention is an automotive gauge with a front accessed removable panel for the installation of an interchangeable, personalized gauge face for the customizing of automobiles.

The American populace is enamored with their automobile. In the strive for individuality, consumers modify the mechanical and/or aesthetic features of their car. It is a multi billion dollar industry in the US. While consumers may buy custom gauges, heretofore such gauges are sealed from the front to prevent the ingress of dust and moisture, have a fixed needle indicator thereon and a permanently affixed gauge face. The only way the look of the gauge can be changed is by replacement of the entire gauge, and even then the design of the gauge face is dictated by the gauge manufacturer.

The gauge kit disclosed herein has a front removable face that is sealed by a elastomeric “O” ring to prevent the ingress of dust and moisture, a keyed removable indicator needle and a removable face that can be replaced by a face the consumer selects or designs, and prints with their computer system from provided electronic format templates and faces. In this way a consumer can have a cluster of automotive gauges bearing such a personalized look as images of his family. Therein a consumer could reach another level in the individualization of car customization.

From the standpoint of the retailer, numerous gauges must be maintained in inventory. Many of these gauges are for similar purposes. In the way of an example, a pressure gauge may be used for oil, water, vacuum or boost pressure. This type of gauge receives a signal from a transducer or has a transducer in it that is calibrated to provide movement of the indicating needle within the specific range of interest. Since this range can generally be adjusted, a single pressure gauge is not discriminating as to the media it is monitoring and can fulfill a plethora of uses. The reason that multiple pressure gauges are necessary to be maintained in inventory is because each gauge has an indicating label such as “Oil Press”, “Exhaust Press”, etc. With the present invention a single pressure gauge is all that must be maintained as the customer is able to personalize the gauge face for the media and range of interest as well as the overall look. This is an attractive option for the gauge kit manufacturer to offer the retailer.

Henceforth, such a personalized gauge kit and method of using would fulfill a long felt need in the car customizing industry. This new invention utilizes and combines known and new technologies in a unique and novel configuration to overcome the aforementioned problems of the prior art.

### SUMMARY OF THE INVENTION

The general purpose of the present invention, which will be described subsequently in greater detail, is to provide a personalized gauge kit and method of using that is able to provide a further step in automobile customizing not seen in the current industry.

It has many of the advantages mentioned heretofore and many novel features that result in a new gauge kit which is not anticipated, rendered obvious, suggested, or even implied by any of the prior art, either alone or in any combination thereof.

In accordance with the invention, an object of the present invention is to provide an improved personalized gauge that is capable of accepting interchangeable faces that may be custom designed, fabricated and installed by the owner.

It is another object of this invention to provide an improved gauge capable of easy front access via a removable cover lens.

It is a further object of this invention to provide a gauge kit that is attractive to a retailer.

It is still a further object of this invention to provide for a minimum set of gauges that may be used to monitor all parameters of an engine.

It is yet a further object of this invention to provide a new, aesthetic customizing component for the automotive industry.

The subject matter of the present invention is particularly pointed out and distinctly claimed in the concluding portion of this specification. However, both the organization and method of operation, together with further advantages and objects thereof, may best be understood by reference to the following description taken in connection with accompanying drawings wherein like reference characters refer to like elements. Other objects, features and aspects of the present invention are discussed in greater detail below.

### BRIEF DESCRIPTION OF THE DRAWINGS

FIG. 1 is a perspective assembly view of the gauge showing the general arrangement of all gauge components;

FIG. 2 is a front view of a large standardized gauge face;

FIG. 3 is a front view of a small standardized gauge face;

FIG. 4 is a rear view of an indicating needle;

FIG. 5 is a front view of a small customized gauge face;

FIG. 6 is a front view of a blank large gauge template configured for use as a speedometer gauge face;

FIG. 7 is a front view of a blank small gauge face template;

FIG. 8 is a front view of a gauge body with a gauge face and the beveled bezel ring installed; and

FIG. 9 is a perspective side view of the beveled bezel ring.

### DETAILED DESCRIPTION

The above description will enable any person skilled in the art to make and use this invention. It also sets forth the best modes for carrying out this invention. There are numerous variations and modifications thereof that will also remain readily apparent to others skilled in the art, now that the general principles of the present invention have been disclosed.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of descriptions and should not be regarded as limiting.

In this description, the present invention is described in the general context of computer executable instructions termed as software programs, capable of being executed by one or more network enabled devices or a stand alone PC. These software programs include but are not limited to routines, programs, objects, components, and data structures that perform particular tasks or implement particular abstract data types. Those skilled in the art will appreciate that the present invention may be practiced with other computer system configurations, including hand held devices, personal digital assistants, multiprocessor systems, microprocessor based or programable consumer electronics, network PC's, microcomputers, mainframe computers and similar devices. In a distributed computer environment, software programs may be located in both local and remote devices as well as on portable storage media. Further, they may be partially or wholly replicated onto a private PC by a downloading process as discussed further herein.

Further this invention comprises a kit which includes the gauge and the software to created and print out a gauge face. The work kit refers to the mated combination of these two components whether or not both are physically contained within a sales packaging media.

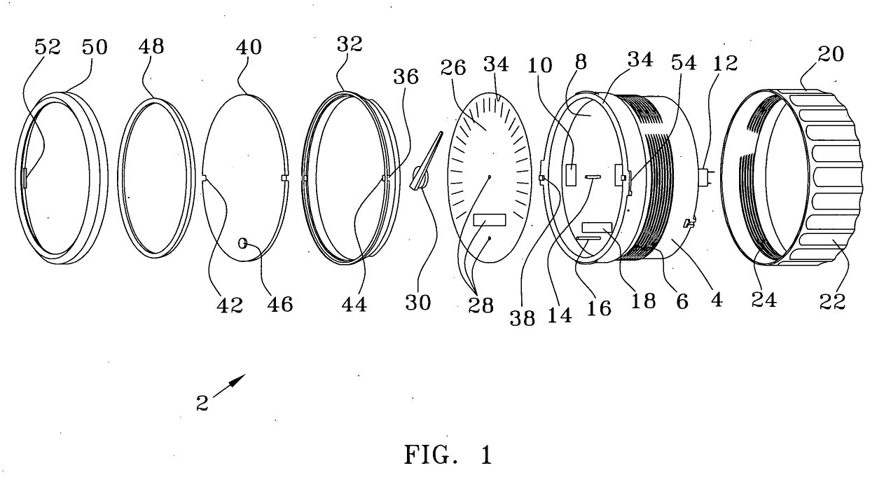

Looking at FIG. 1, it can be seen that the gauge 2 is comprised of a cylindrical gauge body 4 with external threads 6 formed thereon it's exterior surface, that houses a means for receiving and displaying a signal 8 received by a signal source generating means, at least one internal light 10 and at least one electrical connecting means 12 for connection to said signal source generating means and a source of electrical power. The means for receiving and displaying a signal 8 has a rotatable signal output shaft 14, a signal reset means 16 and a digital signal display 18.

Installation lock ring 20 has grippable grooves 22 formed on it's outer surface and internal threads 24 formed therein that are matingly engageable with the external threads 6 on the gauge body 4 such that the lock ring 20 may be attached to the gauge body 4 and rotatingly advanced or retracted about the gauge body's exterior surface.

Gauge face 26 resides on the front face of the means for receiving and displaying a signal 8 and has gauge face orifices 28 there through matingly conformed to the gauge's digital signal displays 18, rotatable signal output shafts 14, and signal reset means 16. The indicating needle 30 has a keyed orifice 32 formed therein (FIG. 4) to matingly accept and frictionally engage the rotatable signal output shaft 14. This allows a needle 30 removed off the output shaft 14 and to be reinstalled in the substantially identical location relative to the output shaft 14, thereby eliminating the requirement for gauge calibration each time the needle 30 is removed for access to the gauge face 26.

Beveled bezel ring 32 has a conical beveled surface 34 (FIG. 9) that tapers toward the center of the gauge 2. The inner diameter of the bezel ring 32 is smaller than the outer diameter of the gauge face 26. With this design, the outer periphery of the gauge face 34 will be hidden from view by the bezel ring 32.

The depth that the means for receiving and displaying a signal 8 resides from the front 34 of the gauge body 4 exceeds the thickness of the bezel ring 32 such that there is a gap between the inner periphery of the bezel ring 32 and the gauge face 26. In this manner illumination from internal light 10 will reflect off of the back beveled surface of the bezel ring 32 and be directed toward the gauge face 26.

The bezel ring 32 has positioning indentations 36 formed on the exterior perimeter that interlock with positioning tabs 38 formed on the outer periphery of the gauge body 4 so as to lock the bezel ring 32 into place and prevent it from rotating within the gauge body 4.

The translucent cover plate 40 has detents 42 formed about the periphery that matingly accept locking protrusions 44 that extend normally from the bezel ring 32. This locks the cover plate 40 with respect to the bezel ring 32 which is locked with respect to the gauge body 4. This prevents the cover plate 40 from being rotated and damaging the signal reset means 16 which extends through the cover glass orifice 46.

Flexible “O” ring 48 is constrained and compressed between trim ring 50 and cover plate 40 when first locking tabs 52 of trim ring 50 are rotatingly located behind second locking tabs 54 of gauge body 4. The lock ring 50 has an external diameter that exceeds the external diameter of the gauge body 4. This allows the dash of the vehicle the gauge 2 is installed into, to be frictional engaged between the trim ring 50 and the lock ring 20.

Although a speedometer gauge has been used for illustrative purposes, all gauges do not have digital signal displays 18, rotatable signal output shafts 14, and signal reset means 16. Any solo configuration or combination thereof may be found in a single gauge. A gauge may be of varying sizes, however, the industry standard is typically to use large gauges in the 3.5 inch diameter range for indicating such parameters as speed and RPM, and small gauges in the 2.5 inch diameter range for indicating such parameters as oil pressure, water temperature, boost etc. These sizes approximate most vehicle's existing gauges, thereby simplifying a retrofit. However, gauges are commercially available that differ significantly from these sizes for custom configurations.

While the preferred embodiment has a cylindrical gauge body 4 with a cylindrical lock ring 20 the gauge body may be of other physical configurations such as square, octagonal, multi sided, oval, elliptical or the such. In this case the external threads formed on the gauge body would be eliminated and a first engageable means would be located on the gauge body's exterior that would be matingly conformed to a second engageable means located on a locking ring that had a geometric configuration compatible with the gauge body.

The gauge 2 and access to a software program are provided together so as to form a kit. The physical packaging of the kit may of any configuration as is commonly used in the industry. The actual physical location of the software program initially may be in the packaging or loaded into memory on a remote computer system, accessible via the internet. Thus, the kit will contain the gauge and access to the software via a portable media'storage device (such as a CD, DVD, floppy disk, memory chip or other storage media commonly known in the industry), or a set of instructions with access permits/codes and a uniform resource location URL designation for a direct link to access the software via the internet.

The software program may be executable on a PC by uploading the software from the portable media storage device onto a PC used the gauge owner, by downloading it from the host's remote computer system onto a PC used the gauge owner, or by indirectly on the host's website via a PC used the gauge owner. The later two will require input of access permits/codes provided to the gauge owner. It has been envisioned that in another embodiment the software may be freely available to the public via a non restricted website for execution or downloading. The expense of maintaining a restricted website may not be necessary if experience shows that abuse by competitors is not encountered.

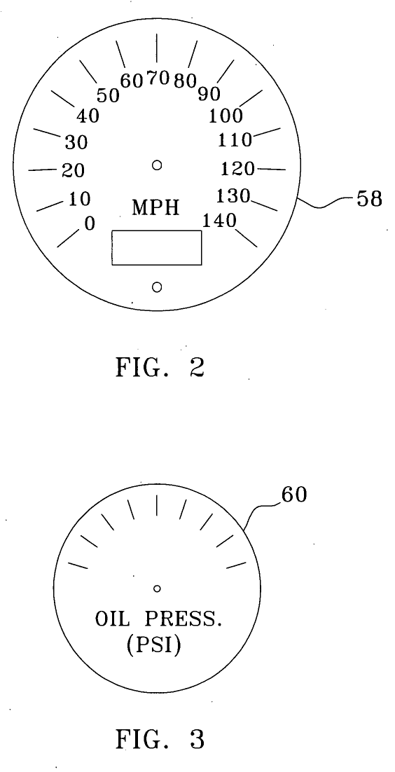

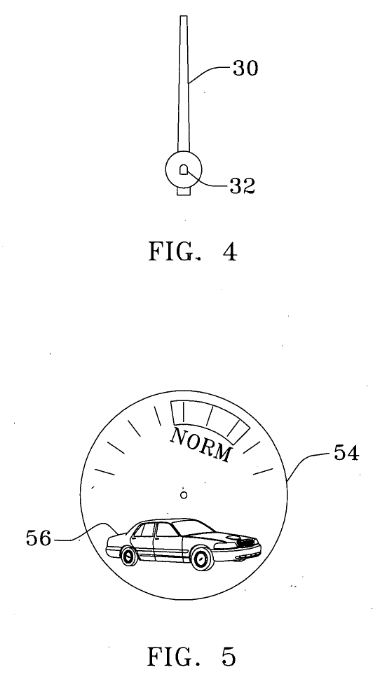

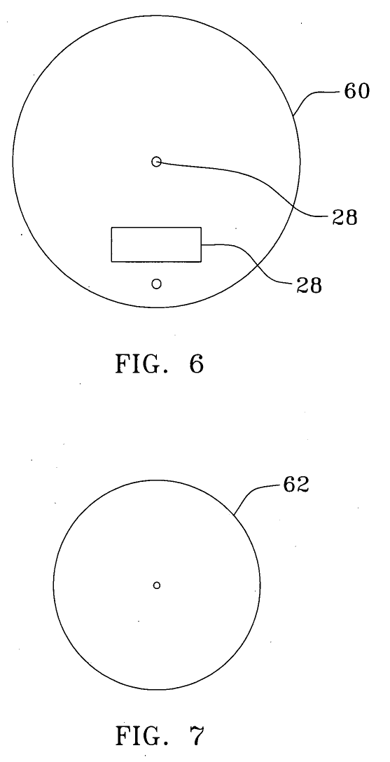

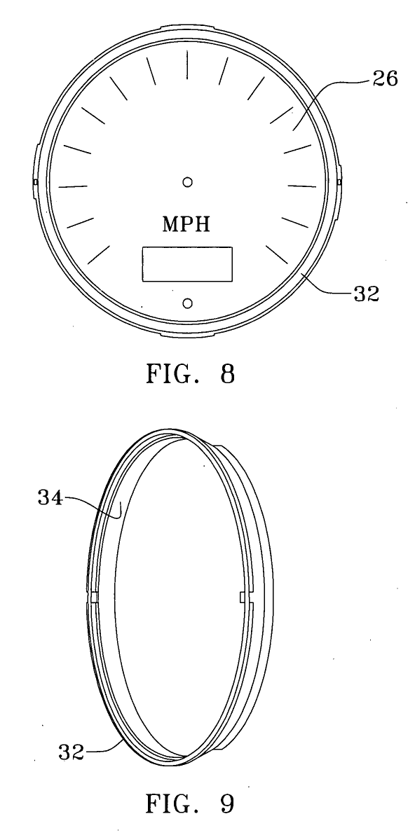

Once accessed, the software program provides all the instructions needed for the gauge owner to print out a pre designed gauge face 58 (FIG. 2) or to make a customized gauge face 54 (FIG. 5) pasting his own graphic images 56 onto a blank template sized for the large gauge 60 (FIG. 6) or a blank template sized for the small gauge 62 (FIG. 7), or in conjunction with a template having basic unit divisions of measurement thereon 60 (FIG. 3). Any amount of customizing can be accomplished by the gauge owner in conjunction with the provided software. The gauge faces can be printed onto paper via a local printer linked to the PC.

Once the gauge face 26 is printed out, preferably on a high quality photographic printing paper for the type of local printer being used (ink jet, laser or led), the gauge face 26 can be cut out about it's periphery, the necessary gauge face orifices cut out by razor knife, and the gauge face 26 affixed to the front face of the means for receiving and displaying a signal 8. The affixation may be accomplished using two sided tape, glue or other suitable means as would be well known in the industry. The Bezel ring's positioning indentations 36 are then aligned with the positioning tabs 38 on the gauge face 32 and put onto the gauge body 4. This hides the edges of the gauge face, giving the entire gauge 4 a professional look. The translucent cover plate 40 is installed onto the bezel ring 32 by aligning detents 42 with locking protrusions 44. The flexible “O” ring 48 is then installed and the locking tabs 52 of trim ring 50 are rotatingly located behind second locking tabs 54 of gauge body 4 to complete the assembly of the customized gauge.

Installation of the assembled gauge 2 is accomplished by pushing the gauge (without the lock ring 20 installed) through the mounting orifice in the vehicle's dash until the trim ring 50 abuts the dash then threadingly advancing the lock ring 20 by hand about the gauge body 4 until the lock ring 20 abuts the das so as to trap a portion of the dash between the lock ring 20 and the trim ring 50. Removal of the gauge would follow the reverse process.

Electrical and signal connections for the internal light source 10, the signal source generating means and electrical power are appropriately made to the gauge's electrical connecting means 12 as would be well known to one skilled in the art. The light source may be a standard incandescent bulb, a single or array of light emitting diodes (LED), or any of a plethora of available DC light emitting sources as are well known in the industry and readily commercially available.

Since the trim ring 50, “O” ring 48, cover plate 40 and bezel ring 32 can be removed from the front of the gauge, a gauge face 26 may be accessed and changed in situ, without disconnecting the gauge 2 or even removing it from the vehicle's dash.

The method of producing a gauge face is as follows. The owner of the gauge kit will be provided in the kit, a gauge 2 and access to gauge face production software via a portable media storage device (such as a CD, DVD, floppy disk, memory chip or other storage media commonly known in the industry), or a set of instructions with access permits/codes and a uniform resource location URL designation for a direct link to access the software via the internet. In the case of a portable media storage device, the owner then installs the media device into a PC connected to a printer and a video display terminal, and uploads the software program into the PC's memory. In the case the kit includes access permits/codes and a uniform resource location URL in place of a media storage device, the user opens a web browser on the PC and inputs the URL to get to a website that has the software program either available for download to the PC being used or that is fully executable from the website. The owner must input the access/permit code into a location indicated by the software program before downloading or use can begin. If the program is downloaded to the PC used by the owner, it may be in a zipped format that requires the owner to install it into the PC he is using before use can begin.

Once the user has the program accessible on the PC they are using, the program is then opened via the executable files and the PC's video display terminal will show a screen view of a set of executable instructions that will guide the owner through a selection of options to choose that will show reformatted conventional gauge face templates (I.E. those gauge faces with scales and media labels), reformatted custom gauge face templates (I.E. conventional gauge faces with additional stylized text or graphic images thereon) or blank templates (I.E. circle templates.) All gauge faces have pre set dimensions (diameters and gauge face orifice outlines 28) compatible with the various sizes of gauges available in the kits. The owner may then “copy and paste”, manipulate and place his own graphic or text images into the gauge face templates. The gauge face images may then be store in the PC's memory, printed onto a gauge face media such as glossy, photographic quality paper or both. The user then cuts out the gauge face 26 and any associated gauge face orifices 28 and affixes the gauge face 26 to the front face of the means for receiving and displaying a signal 8. Assembly and installation of the gauge 2 follows the procedure described herein.

It is also an option to allow free access to the gauge face customizing and printing software in any of the above described formats.

It is another option to provide at least one custom pre-made, precut gauge faces in the kit box either with or without access to the software described herein.

In a new type of gauge, the face plate rotates and the indicating needle remains stationary. While the internal mechanisms of their gauge body differs from those discussed in the present invention, the customization of the gauge faces and the front access features of the present invention may still be utilized. While the physical configuration of such gauges differ, it would be well known to one skilled in the art to utilize many of the aspects of the present invention therein.

Having thus described the invention, what is claimed as new and desired to be secured by Letters Patent is as follows:

1. A kit for making a personally stylized indicating gauge comprised of:
an indicating gauge;
a computer software program executable by a PC providing modifiable and printable gauge face templates dimensionally compatible with said indicating gauge.

2. The kit of claim 1 wherein said software program is provided in an online PC accessible executable format with a user restricted access, wherein said access to said software program is granted by input of access codes or permits which are provided therein said kit.

3. The kit of claim 1 wherein said software program is provided in said kit in a computer readable, external storage media capable of being uploaded onto a PC for execution.

4. The kit of claim 1 wherein said software program is provided in a PC downloadable format available from an online user restricted access site, wherein said access to said site is granted by input of access codes or permits which are provided therein said kit.

5. The kit of claim 1 wherein said gauge further comprises:
a cylindrical gauge body with external threads formed thereon;
a lock ring with internal threads formed thereon matingly compatible for engagement with said external threads;
a means for receiving and displaying a signal housed in said gauge body;
at least one light housed in said gauge body;
at least one means for connection to a signal source generating means and for connection to a source of electrical power;
a gauge face;
an indicating needle,
a light deflection ring;
a translucent cover plate;
a flexible, compressible sealing ring; and
a removable bezel ring.

6. The kit of claim 5 wherein said indicating needle has a keyed recess formed thereon and matingly conformed to a positioning arm extending from said means for receiving and displaying a signal.

7. The kit of claim 6 wherein said gauge body further comprises two internal lights housed therein.

8. The kit of claim 7 wherein said signal is displayed by an indicating needle residing adjacent said gauge face, and engaged with said positioning arm extending from said means for receiving and displaying a signal.

9. The kit of claim 8 wherein said means for receiving and displaying a signal generates and displays a digital readout of accumulated or maximum levels of a measured parameter based on said signal.

10. The kit of claim 8 wherein said software program is provided in an online PC accessible executable format with a user restricted access, wherein said access to said software program is granted by input of access codes or permits which are provided therein said kit.

11. The kit of claim 8 wherein said software program is provided in said kit in a computer readable, external storage media capable of being uploaded onto a PC for execution.

12. The kit of claim 8 wherein said software program is provided in a PC downloadable format available from an online user restricted access site, wherein said access to said site is granted by input of access codes or permits which are provided therein said kit.

13. The kit of claim 8 wherein said software program is provided in an online PC accessible executable format with unrestricted access to said software program.

14. The kit of claim 8 wherein said software program is provided in a PC downloadable format available from an online access site.

15. A method making a personalized gauge comprising the steps of:
accessing an interactive software program for the design and printing of customized gauge faces;
inputting an access code or permit where necessary to enable executable access to said software program;
interactively designing a stylized gauge face with said software program from a personal computer;
printing said stylized gauge face from a printer connected to said personal computer onto a sheet media;
cutting said gauge face out from said sheet media including removing any gauge face orifices necessary for the installation of the gauge face;
affixing said gauge face onto the front face of a means for receiving and displaying a signal housed in a gauge body;
installing an indicating needle onto a positioning arm extending from said means for receiving and displaying a signal;
installing a beveled light ring onto said gauge body;
installing a translucent cover plate onto said beveled light ring;
installing an “O” ring into an outer trim ring and installing said trim ring onto said gauge body so as to constrain and seal said trim ring, said “O” ring, said cover plate and said light ring to said gauge body.

16. A gauge that allows front access for interchanging a gauge face comprising:
a cylindrical gauge body with external threads formed thereon;
a lock ring with internal threads formed thereon matingly compatible for engagement with said external threads;
a means for receiving and displaying a signal housed in said gauge body;
at least one light housed in said gauge body;
at least one means for connection to a signal source generating means and for connection to a source of electrical power, wherein said meas has a signal indicating shaft extending therefrom;
a removable, replaceable gauge face;
an indicating needle keyed to said signal indicating shaft
a beveled light deflection ring;
a translucent cover plate;
a flexible, compressible sealing ring; and
a removable bezel ring.
